(19) United States
(12) Patent Application Publication
(10) Pub. No.: US 2026/0209937 A1
(43) Pub. Date: Jul. 23, 2026

(54) METHOD OF MANUFACTURING MAGNESIUM INDIUM OXIDE THIN FILMS

(71) Applicants: ENTEGRIS, INC., Billerica, MA (US); INDUSTRY-UNIVERSITY COOPERATION FOUNDATION, HANYANG UNIVERSITY, Seoul (KR)

(72) Inventors: SungHae Lee, Suwon-si (KR); Jin-Seong Park, Seongnam-si (KR); Chi Hoon Lee, Seoul (KR); Ji-Su Bae, Seoul (KR)

(21) Appl. No.: 19/454,235

(22) Filed: Jan. 20, 2026

(30) Foreign Application Priority Data
Jan. 23, 2025 (KR) 10-2025-0010359

(51) Int. Cl. C23C 16/455; C23C 16/40; C23C 16/56

(52) U.S. Cl. CPC C23C 16/45531; C23C 16/403; C23C 16/45553; C23C 16/56

(57) ABSTRACT

A method of manufacturing a MgInₓO_{y} film (where x>0 and y>0) includes performing one or more cycles of an atomic layer deposition process. Each of the one or more cycles includes performing a first process and a second process. The first process includes supplying a first precursor containing magnesium to a substrate, and supplying a first reactant to the substrate such that the first reactant reacts with the first precursor to form a first intermediate layer on the substrate. The second process includes supplying a second precursor containing indium to the substrate, and supplying a second reactant to the substrate such that the second reactant reacts with the second precursor to form a second intermediate layer on the substrate.

### CROSS-REFERENCE TO RELATED APPLICATION

This application is based upon and claims the benefit of priority from Korean Patent Application No. 10-2025-0010359, filed on Jan. 23, 2025, the entire contents of which are incorporated herein by reference.

### TECHNICAL FIELD

The present disclosure relates to a method of manufacturing a magnesium indium oxide film, and more particularly, to a method of manufacturing a magnesium indium oxide (MgInₓO_{y}) film using an atomic layer deposition (ALD) process.

### BACKGROUND

In the next-generation display and semiconductor industries, diverse research is being conducted to implement cutting-edge technologies such as the Internet of Things (IoT) and artificial intelligence (AI). Consequently, demand for and research on new materials capable of implementing these technologies are increasing. An oxide semiconductor is one of the emerging materials that attract attention in the industry. The oxide semiconductor is capable of exhibiting high mobility characteristics based on the wide 5s orbital of indium, forming a wide band gap through combination with oxygen (O), and dramatically reducing an off-current.

### SUMMARY

Various embodiments of the present disclosure provide a method of manufacturing a MgInₓO_{y} film, which has improved process efficiency and is capable of forming a MgInₓO_{y} film having excellent hydrogen resistance and electrical conductivity using an atomic layer deposition process.

A method of manufacturing a MgInₓO_{y} film (where x>0 and y>0) according to one aspect of the present disclosure may include performing one or more cycles of an atomic layer deposition process. Each of the one or more cycles may include performing a first process and a second process. The first process may include supplying a first precursor containing magnesium (Mg) to a substrate, and supplying a first reactant to the substrate such that the first reactant reacts with the first precursor to form a first intermediate layer on the substrate. The second process may include supplying a second precursor containing indium (In) to the substrate, and supplying a second reactant to the substrate such that the second reactant reacts with the second precursor to form a second intermediate layer on the substrate.

According to one aspect of the present disclosure, the first process or the second process may be performed at a temperature of 100 degrees C. to 400 degrees C.

According to one aspect of the present disclosure, each of the one or more cycles may include performing the first process n times (where n is an integer greater than or equal to 1) and the second process m times (where m is an integer greater than or equal to n).

According to one aspect of the present disclosure, a ratio m/n may have a value in a range of 2 to 8.

According to one aspect of the present disclosure, in the MgInₓO_{y} film, the ratio of the number of In atoms to the sum of the number of Mg and In atoms may have a value in a range of 43.3 at. % to 72 at. %.

According to one aspect of the present disclosure, the method may further include performing a heat treatment process on the substrate after performing the one or more cycles. The heat treatment process may be performed at a temperature of 500 degrees C. or lower.

According to one aspect of the present disclosure, the MgInₓO_{y} film may have a (311) crystal plane.

According to one aspect of the present disclosure, the MgInₓO_{y} film may have an inverse spinel structure.

According to one aspect of the present disclosure, the first precursor may include at least one of Mg(EtCp)₂, Mg(Cp)₂, Mg(thd)₂, or derivatives thereof.

According to one aspect of the present disclosure, the second precursor may include at least one of TMI, DADI, DMION, DBADMIn, or derivatives thereof.

According to one aspect of the present disclosure, the MgInₓO_{y} film may contain impurities.

According to one aspect of the present disclosure, the impurities may include at least one of carbon (C), nitrogen (N), or hydrogen (H).

According to one aspect of the present disclosure, in each of the one or more cycles, the first process and the second process may be performed sequentially, or the second process and the first process may be performed sequentially.

A film according to another aspect of the present disclosure may be a MgInₓO_{y} film (where x>0 and y>0). The film may contain impurities.

According to another aspect of the present disclosure, the impurities include at least one of carbon (C), nitrogen (N), or hydrogen (H).

According to another aspect of the present disclosure, in the MgInₓO_{y} film, the ratio of the number of In atoms to the sum of the number of Mg and In atoms may have a value in the range of 43.3 at. % to 72 at. %.

According to another aspect of the present disclosure, the film may be formed by performing a heat treatment process, and the heat treatment process may be performed at a temperature of 500 degrees C. or lower.

According to another aspect of the present disclosure, the MgInₓO_{y} film may have a (311) crystal plane.

According to another aspect of the present disclosure, the MgInₓO_{y} film may have an inverse spinel structure.

According to the present disclosure, a MgInₓO_{y} film having excellent hydrogen resistance and electrical conductivity can be formed using an atomic layer deposition process, and further, the process efficiency when forming the MgInₓO_{y} film can be improved.

### BRIEF DESCRIPTION OF THE DRAWINGS

FIG. 1 is a flowchart illustrating a method of manufacturing a MgInₓO_{y} film (where x>0 and y>0) according to one embodiment of the present disclosure.

FIG. 2 shows the crystallinity analysis results for MgInₓO_{y} films of Examples 1 to 5 before heat treatment using XRD.

FIG. 3 shows the crystallinity analysis results for the MgInₓO_{y} films of Examples 1 to 5 after heat treatment using XRD.

FIG. 4 shows the crystallinity analysis results for MgInₓO_{y} films of Comparative Examples 1 to 3 after heat treatment using XRD.

FIG. 5 shows the results of X-Ray Photoelectron Spectroscopy (XPS) O 1s analysis performed on the MgInₓO_{y} films of Examples 1 to 5 that were not heat treated.

FIG. 6 is a diagram illustrating a device to which a MgInₓO_{y} film is applied.

FIG. 7 is a graph illustrating the characteristics of devices of Examples 6 to 10 listed in Table 6.

FIG. 8 is a graph showing the results of stress evaluations on the devices of Examples 6 to 10.

FIG. 9 is a graph showing changes in device characteristics due to hydrogen (H) exposure for Examples 6 to 10 and Comparative Example 4.

### DETAILED DESCRIPTION

In describing the present disclosure, if it is determined that related known functions which are obvious to those skilled in the art and may unnecessarily obscure the gist of the present disclosure, the detailed description thereof will be omitted.

In this specification, the expression such as “supplying a material to a substrate” should be understood to include not only directly supplying a material to the surface of an exposed substrate, but also supplying a material to a substrate on which a film or a pattern is formed.

In this specification, the expression such as “derivative of a specific substance” includes compounds whose groups are replaced with various substituents or functional groups including but not limited to, one or more hydrogen atoms, alkyl groups, aryl groups, alkoxy groups, halogens, nitro groups, amine groups, carboxyl groups, ester groups, ketone groups and the like while maintaining the basic structure or core skeleton of a specific substance, and variants of a specific substance produced by chemical or physical treatments such as epoxidation, reduction, oxidation, hydrogenation, dehydrogenation, amination, methylation, and ethylation. In addition, the “derivative” of a compound as used herein includes various compounds formed by blending of the above compounds and combinations of ratios as well as the above-described substitutions and chemical transformations. It should be noted that this definition is exemplary, and the scope of the present disclosure is not limited by the derivatives defined above.

In this specification, the expression used when expressing a numerical range, such as “A to B”, should be understood to mean that A and B are included in the numerical range. That is, the expression such as “A to B” should be understood to mean “A or more and B or less.”

In this specification, the expression such as “at least one of X, Y, or Z” should be understood to mean not only any one of X, Y and Z, but also any possible combination of two or more of X, Y and Z.

When manufacturing a device or the like using such an oxide semiconductor, hydrogen (H) may be introduced into the oxide semiconductor through various routes. For example, hydrogen remaining in a chamber may be introduced during a deposition process, or H existing in the ambient air or hydrogen existing within other components (e.g., a buffer film, a gate insulating film, a passivation film, etc.) of a device may be diffused into the oxide semiconductor during a heat treatment process. Hydrogen unintentionally introduced through subsequent processes may cause defects within the oxide semiconductor, reduce electron mobility, and lower the reliability of the device, thereby causing deterioration of the oxide semiconductor.

MgIn₂O₄ is an oxide semiconductor with hydrogen resistance, and degradation by hydrogen can be minimized in MgIn₂O₄. MgIn₂O₄ has an inverse spinel structure in terms of crystal structure, and its unit cell is Mg₈In₁₆O₃₂. In the inverse spinel structure of the unit cell of MgIn₂O₄ (i.e., Mg₈In₁₆O₃₂), oxygen ions (O²⁻) constitute 32 octahedral sites and 64 tetrahedral sites. Of the 32 octahedral sites, magnesium ions (Mg²⁺) are located in 8 sites, indium ions (In³⁺) are located in the other 8 sites, and the remaining 16 sites exist as interstitial sites. Of the 64 tetrahedral sites, In 3 are located in 8 sites, and the other 56 sites exist as interstitial sites. MgIn₂O₄ with the above-described inverse spinel structure can have high conductivity and can exhibit high doping efficiency based on a large number of interstitial sites.

The high hydrogen resistance of MgIn₂O₄ is known to be mainly attributable to the magnesium (Mg) and crystal structure of MgIn₂O₄. Specifically, Mg in MgIn₂O₄ has a high binding energy of 4.1 eV with oxygen (O) and is stably bound with oxygen, thereby minimizing oxygen desorption due to hydrogen reduction in MgIn₂O₄. In addition, magnesium has a hydrogen storage property strong enough to be utilized as a hydrogen storage material, which minimizes hydrogen desorption in subsequent processes, thereby minimizing the influence of hydrogen on MgIn₂O₄. In addition, since MgIn₂O₄ has a stable crystal structure, oxygen vacancies where hydrogen can be located are minimized, consequently suppressing introduction of hydrogen into MgIn₂O₄.

As a method of manufacturing a MgInₓO_{y} film, such as a MgIn₂O₄ film, many manufacturing methods based on a sputtering process have been studied in the past. When manufacturing a MgInₓO_{y} films using a sputtering process, the film can be deposited relatively quickly, but various problems occur during the manufacturing process or in the finally formed MgInₓO_{y} film. Specifically, the MgInₓO_{y} film available immediately after the sputtering process does not have sufficient electrical conductivity, and additional processes such as ion implantation or hydrogen annealing are essentially required to improve the electrical conductivity. This causes problems in that the process time and cost for manufacturing the MgInₓO_{y} film increase. Furthermore, the MgInₓO_{y} film formed by the sputtering process has polycrystalline planes of (220), (222), (400), and (422) in addition to the (311) crystal plane associated with the inverse spinel structure. In addition, grain boundaries formed in large numbers within the film due to polycrystalline planes may cause carrier scattering and charge trapping, which may result in deterioration of charge mobility and reliability of the device using the MgInₓO_{y} film. In addition, the MgInₓO_{y} film formed by the sputtering process have poor step coverage, making them unsuitable for device industries that require uniform film properties for high aspect ratio structures.

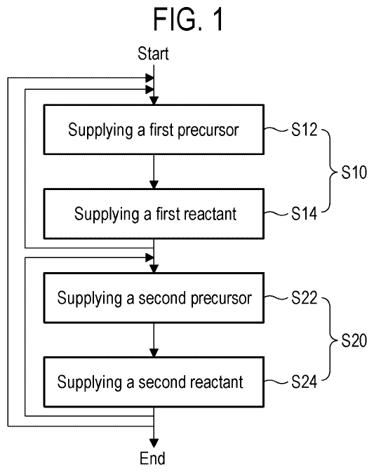

FIG. 1 is a flowchart illustrating a method of manufacturing a MgInₓO_{y} film (where x>0 and y>0) according to an embodiment of the present disclosure.

Referring to FIG. 1, the method of manufacturing a MgInₓO_{y} film (where x>0 and y>0) according to one embodiment includes performing one or more cycles. Each of the one or more cycles may include performing a first process (S10) and a second process (S20). As used herein, the term “cycle” means a minimum unit process in which the same process is repeated. Therefore, when two or more cycles are performed, the first process (S10) and the second process (S20) may be performed alternately and repeatedly. Although FIG. 1 illustrates that the first process (S10) and the second process (S20) are performed sequentially in a cycle, the order in which the two processes are performed may be reversed. Therefore, the second process (S20) may be performed before the first process (S10) in the cycle.

The first process (S10) and the second process (S20) are processes for forming different materials, and each of the first process (S10) and the second process (S20) includes an atomic layer deposition process. For example, the first process (S10) may include an atomic layer deposition process for forming a first intermediate layer on a substrate, and the second process (S20) may include an atomic layer deposition process for forming a second intermediate layer composed of a different material from the first intermediate layer on the first intermediate layer.

The first process (S10) includes supplying a first precursor to the substrate (S12) and supplying a first reactant to the substrate (S14). The first reactant can react with the first precursor on the substrate. A first intermediate layer can be formed on the substrate through the reaction between the first precursor and the first reactant.

For example, the first precursor may contain magnesium. The first precursor may include at least one of Mg(EtCp)₂, Mg(Cp)₂, Mg(thd)₂, or derivatives thereof. The first reactant may contain oxygen. For example, the first reactant may include O₃. The first intermediate layer may contain magnesium derived from the first precursor and O derived from the first reactant. The first intermediate layer may include a MgO layer.

For example, the first process (S10) may include a thermal atomic layer deposition (TALD) process performed at a temperature higher than the room temperature (e.g., 25 degrees C.). The first process (S10) may be performed at a temperature of 100 degrees C. to 400 degrees C. In this case, even if a pattern having a high aspect ratio is formed on the substrate, a first intermediate layer having a uniform step coverage can be formed compared to a case where the first process is performed using a plasma enhanced atomic layer deposition (PEALD) process. However, the first process (S10) in the present disclosure is not limited to the TALD process. It should be understood that a person skilled in the art can select an appropriate vapor deposition process from among the TALD process and the PEALD process in consideration of the environment in which the first process (S10) is performed.

For example, the first process (S10) may further include a purge process. One first process (S10) may include one or more purge processes. One first process (S10) may include supplying a first precursor (S12), a purge process, supplying a first reactant (S14), and a purge process, which are performed sequentially. The purge process may be performed using an inert gas or an N₂ gas.

The second process (S20) includes supplying a second precursor to the substrate (S22) and supplying a second reactant to the substrate (S24). The second reactant can react with the second precursor on the substrate. A second intermediate layer can be formed on the substrate through the reaction between the second precursor and the second reactant.

For example, the second precursor may contain In. The second precursor may include at least one of trimethylindium (TMI), 3-dimethylaminopropyl) dimethylindium (DADI), dimethyl [N-(tert-butyl)-2-methoxy-2-methylpropan-1-amine]indium (DMION), (N,N′-di-tert butylacetimidamido)dimethyllindium (DBADMIn), or derivatives thereof. The second reactant may contain oxygen. The second reactant may include O₃. The second intermediate layer may contain In derived from the second precursor and oxygen derived from the second reactant. The second intermediate layer may include an In₂O₃ layer.

For example, the second process (S20) may include a TALD process performed at a temperature higher than the room temperature (e.g., 25 degrees C.). The second process (S20) may be performed at a temperature of 100 degrees C. to 400 degrees C. In this case, as described in the first process (S10), a second intermediate layer having a uniform step coverage can be formed compared to a case where the PEALD process is performed. However, the second process (S20) is not limited to the TALD process. It should be understood that a person skilled in the art can select an appropriate vapor deposition process among the TALD process and the PEALD process by considering the environment in which the second process (S20) is performed.

For example, the second process (S20) may further include a purge process. One second process (S20) may include one or more purge processes. One second process (S20) may include supplying a second precursor (S22), a purge process, supplying a second reactant (S24), and a purge process, which are performed sequentially. The purge process may be performed using an inert gas or an N₂ gas.

For example, when the first process (S10) and the second process (S20) are sequentially performed in a cycle, in the second process (S20), the second precursor may be supplied to the substrate on which the first intermediate layer is formed, and the second intermediate layer may be formed on the first intermediate layer. Alternatively, when the second process (S20) and the first process (S10) are sequentially performed in a cycle, in the first process (S10), the first precursor may be supplied to the substrate on which the second intermediate layer is formed, and the first intermediate layer may be formed on the second intermediate layer.

Through the first process (S10) and the second process (S20), a MgInₓO_{y} film is formed from the first intermediate layer and the second intermediate layer. For example, the MgInₓO_{y} film can be formed by physical and chemical bonding and diffusion of the first intermediate layer and the second intermediate layer. At this time, when the ratio of the number of In atoms to the sum of the number of magnesium and indium atoms in the MgInₓO_{y} film (i.e., (x/(1+x))*100 at. %, hereinafter referred to as “In concentration”) has a value in a range of 43.3 at. % to 72 at. %, the MgInₓO_{y} film can have excellent hydrogen resistance and electrical conductivity (see the Examples described later). This appears to be because the MgInₓO_{y} film has a ratio of the number of indium atoms similar to that of a MgIn₂O₄ film in the above-described numerical range, and therefore forms a large number of inverse spinel structures so as to exhibit excellent properties as an oxide semiconductor. In this regard, the ratio of the number of atoms in the MgInₓO_{y} film can be controlled by adjusting the process conditions of the first process (S10) and the second process (S20) to differently adjust the ratio of the first intermediate layer and the second intermediate layer.

For example, the ratio of the number of atoms in the MgInₓO_{y} film may vary depending on the ratio of the thickness of the first intermediate layer formed in the first process (S10) and the thickness of the second intermediate layer formed in the second process (S20). The thickness of the first intermediate layer formed by performing the first process (S10) once may be 0.5 Å to 1.8 Å. If the thickness of the first intermediate layer formed by performing the first process once is too thin, the proportion of Mg in the MgInₓO_{y} film may become too low, or the first process (S10) may be required to be performed multiple times to increase the proportion of Mg, which lowers the process efficiency. If the thickness of the first intermediate layer formed by performing the first process once is too thick, the proportion of Mg in the MgInₓO_{y} film may become too high, or an MgInₓO_{y} film having a sufficient thickness compared to the amount of Mg introduced may not be formed. The thickness of the second intermediate layer formed by performing the second process (S20) once may be 0.4 Å to 1.5 Å. If the thickness of the second intermediate layer formed by performing the second process once is too thin, the proportion of indium in the MgInₓO_{y} film becomes too low, or the second process (S20) may be required to be performed multiple times to increase the proportion of indium, which lowers the process efficiency. If the thickness of the second intermediate layer formed by performing the second process once is too thick, the proportion of indium in the MgInₓO_{y} film becomes too high, or an MgInₓO_{y} film having a sufficient thickness compared to the amount of In introduced may not be formed.

For example, the ratio of the number of atoms in the MgInₓO_{y} film may vary depending on the number of times the first process (S10) and the second process (S20) are performed in one cycle. For example, when the first process (S10) is performed n times (where n is an integer greater than or equal to 1) and the second process (S20) is performed m times (where m is an integer greater than or equal to 1) in one cycle, the ratio of the number of atoms in the MgInₓO_{y} film may be controlled by adjusting n and m. Preferably, m may be greater than or equal to n, and more preferably, the ratio m/n may have a value within a range of 2 to 8. In this case, a MgInₓO_{y} film having excellent electrical conductivity and hydrogen resistance can be formed.

The MgInₓO_{y} film formed through the first process (S10) and the second process (S20) may have an inverse spinel structure and a (311) crystal plane associated therewith. Furthermore, the MgInₓO_{y} film formed through the first process (S10) and the second process (S20) may have a relatively smaller amount of polycrystalline planes compared to a MgInₓO_{y} film formed by sputtering. Accordingly, when the MgInₓO_{y} film formed through the first process (S10) and the second process (S20) is used in a device, it is possible to minimize performance degradation due to grain boundaries, and to improve charge mobility within the MgInₓO_{y} film. Consequently, by applying the above-described MgInₓO_{y} film to a device, the electrical properties and reliability of the device can be improved.

According to one embodiment of the present disclosure, after the MgInₓO_{y} film is formed by performing one or more cycles, an additional heat treatment process may be performed on the substrate on which the MgInₓO_{y} film is formed. The MgInₓO_{y} film before the heat treatment process is performed may have a partially amorphous region in addition to the above-described crystalline region. However, by additionally performing the heat treatment process, the crystallinity of the MgInₓO_{y} film can be further improved. For example, through the heat treatment process, the grain boundaries of the MgInₓO_{y} film can be reduced, and the (311) crystal plane can be increased. Accordingly, when the heat-treated MgInₓO_{y} film is applied to a device, the properties of the device can be further improved. However, the above-described heat treatment is not essential for the manufacture of the MgInₓO_{y} film. Even if the heat treatment is not performed on the MgInₓO_{y} film, the MgInₓO_{y} film can have sufficient electrical conductivity (see Table 4 described below). That is, a person skilled in the art will be able to maximize the efficiency of the process by excluding heat treatment or performing heat treatment only for a short period of time.

For example, the heat treatment process may be performed at a temperature of 500 degrees C. or lower. Preferably, the heat treatment process may be performed at a temperature of 100 degrees C. to 500 degrees C. If the temperature of the heat treatment process is too low (for example, lower than 100 degrees C.), the crystallization of the MgInₓO_{y} film may not progress sufficiently. If the temperature of the heat treatment process is too high (for example, higher than 500 degrees C.), the reliability of the device may deteriorate due to deformation of the MgInₓO_{y} film or other components within the device to which the film is applied. For example, the heat treatment process may be performed for 30 minutes to 4 hours. If the time of the heat treatment process is too short (for example, shorter than 30 minutes), the crystallization of the MgInₓO_{y} film may not progress sufficiently. If the time of the heat treatment process is too long (for example, longer than 4 hours), the reliability of the device may deteriorate and the process efficiency may decrease due to deformation of the MgInₓO_{y} film or other components within the device to which the film is applied.

The MgInₓO_{y} film formed through the first process (S10) and the second process (S20) may contain impurities. As used herein, the term “impurities” refers to elements that may be introduced into the film, other than magnesium, indium, and oxygen. For example, the impurities may be derived from the precursor (e.g., the first precursor or the second precursor) or the reactant (e.g., the first reactant or the second reactant) supplied during the progression of the cycle. That is, as the atomic layer deposition process progresses, elements present in the precursor or reactant for the atomic layer deposition process may be introduced into the MgInₓO_{y} film as impurities. The impurities may include at least one of carbon, nitrogen, or hydrogen. For example, even if the heat treatment process is not performed, the MgInₓO_{y} film may contain hydrogen as an impurity, wherein hydrogen may be derived from the precursor or the reactant in the first process (S10) or the second process (S20). In the XPS O1s analysis for the MgInₓO_{y} film on which the heat treatment process has not been performed, the atomic percentage of each element of the impurities may be 3 at. % or less. For example, in the XPS O1s analysis for the MgInₓO_{y} film on which the heat treatment process has not been performed, when the atomic percentage of H for O—H is calculated based on the percentage composition of O and the percentage of O—H of O1s, 3 at. % or less of H may be contained. Similarly, in the XPS O1s analysis for the MgInₓO_{y} film on which the heat treatment process has not been performed, when the atomic percentage of C for O—C is calculated based on the percentage composition of O and the percentage of O—C of O1s, 3 at. % or less of C may be contained, and when the atomic percentage of N for O—N is calculated based on the percentage composition of O and the percentage of O—N of O 1s, 3 at. % or less of N may be contained. If the atomic percentage of each element of the impurities exceeds 3 at. %, it may deteriorate the properties of the MgInₓO_{y}film. Therefore, it is required to control the atomic percentage of each element of the impurities to 3 at. % or less.

Hereinafter, the MgInₓO_{y} film formed through the method according to the present disclosure will be described in more detail through Examples.

Table 1 below shows the results of XPS composition analysis of the ratio of the number of atoms in the MgInₓO_{y} film when the performance ratio (i.e., m/n) of the first and second processes was changed in one cycle. In manufacturing the MgInₓO_{y} films of the Examples and Comparative Examples in Table 1 below, the temperatures in the first and second processes were maintained at 250 degrees C., Mg(EtCp)₂ heated to 60 degrees C. was used as the first precursor, TMI heated to 30 degrees C. was used as the second precursor, and O₃ having a concentration of 210 g/m³ was used as the first and second reactants. Table 1 shows the compositions of the films when an additional heat treatment was performed for the Examples and Comparative Examples. The heat treatment was performed at 500 degrees C. for 2 hours using a dry air (20% of O₂ gas and 80% of N₂ gas). In the Examples described below, unless otherwise stated, heat treatment was performed under the same conditions as described above.

TABLE 1

| | | Atomic composition | | | | In |
|---|---|---|---|---|---|---|
| | | (at. %) | | | | Concentration |
| | m/n | In | Mg | O | In:Mg:O | (at. %) |
| Comparative | 1/2 | 8.7 | 37.1 | 54.2 | 0.2:1:1.5 | 20.2 |
| Example 1 | | | | | | |
| Example 1 | 2 | 19.4 | 25.4 | 55.2 | 0.8:1:2.2 | 43.3 |
| Example 2 | 3 | 22.5 | 22.4 | 55.1 | 1.0:1:2.6 | 50.1 |
| Example 3 | 4 | 25.2 | 19.4 | 55.4 | 1.3:1:2.9 | 56.5 |
| Example 4 | 6 | 29.1 | 15.3 | 55.6 | 1.9:1:3.6 | 65.5 |
| Example 5 | 8 | 31.7 | 12.3 | 56.0 | 2.6:1:4.6 | 72.0 |
| Comparative | 16 | 36 | 6.2 | 57.8 | 5.8:1:9.3 | 84.0 |
| Example 2 | | | | | | |
| Comparative | 46 | 39.5 | 2.1 | 58.4 | 18.7:1:27.6 | 94.7 |
| Example 3 | | | | | | |

According to the Examples and Comparative Examples, as m increases relative to n, the ratio of the number of In atoms to the number of Mg atoms increases.

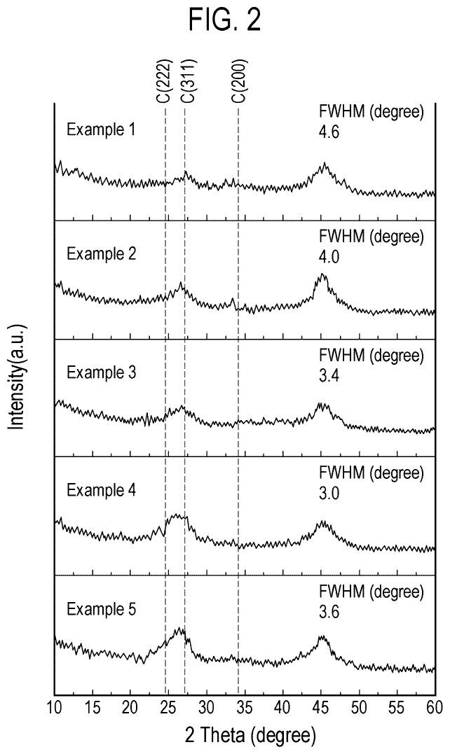

FIG. 2 shows the results of crystallinity analysis of the MgInₓO_{y} films of Examples 1 to 5 before heat treatment using XRD. Referring to FIG. 2, the MgInₓO_{y} films of Examples 1 to 5 all have a peak confirmed at the (311) crystal plane. As described above, the (311) crystal plane is a plane related to the inverse spinel structure. Since the MgInₓO_{y} films of Examples 1 to 5 have a composition similar to that of a MgIn₂O₄ film, it appears that the MgInₓO_{y} films have a peak at the (311) crystal plane. Consequently, by controlling the performance of the first process and the second process so that the ratio m/n has a value of 2 to 8, it is possible to form a MgInₓO_{y} film having a large number of inverse spinel structures, and there, it is possible to form a MgInₓO_{y} film having high conductivity and high doping efficiency.

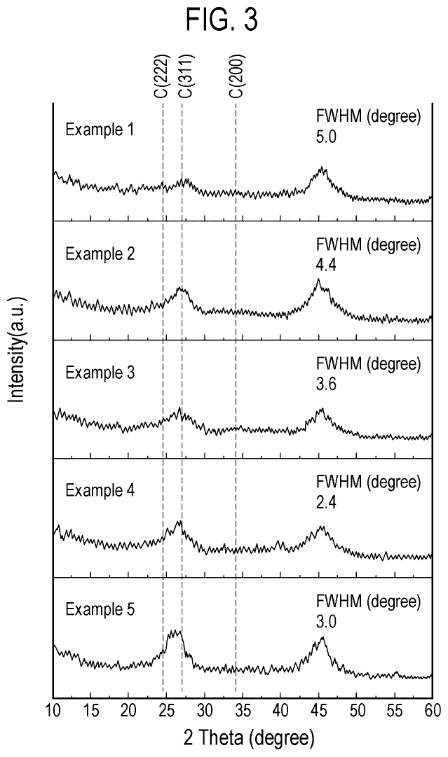

FIG. 3 shows the results of crystallinity analysis of the MgInₓO_{y} films of Examples 1 to 5 after heat treatment using XRD. Referring to FIG. 3, as before the heat treatment, all the MgInₓO_{y} films of Examples 1 to 5 have a peak at the (311) crystal plane. This confirms that the MgInₓO_{y} films have an inverse spinel structure even after the heat treatment. Consequently, it is confirmed that the MgInₓO_{y} films can have high conductivity and high doping efficiency due to the inverse spinel structure.

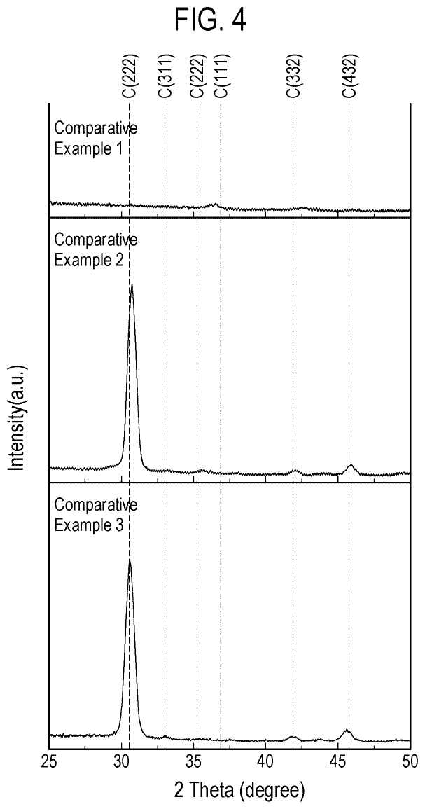

FIG. 4 shows the results of crystallinity analysis of the MgInₓO_{y} films of Comparative Examples 1 to 3 after heat treatment using XRD. Referring to FIG. 4, the peak at the (311) crystal plane is not confirmed in the MgInₓO_{y} films of Comparative Examples 1 to 3. Rather, in the case of Comparative Example 1, a peak is weakly confirmed near the (111) plane associated with MgO, and in the cases of Comparative Examples 2 and 3, a peak is confirmed near the (222) plane associated with In₂O₃. This is because, when the MgInₓO_{y} film of Comparative Example 1 is formed, the first process of forming MgO was performed relatively more frequently than in the Examples, and when the MgInₓO_{y} films of Comparative Examples 2 and 3 are formed, the second process of forming In₂O₃ was performed relatively more frequently than in the Examples. Consequently, if the ratio m/n is too small or too large (e.g., less than 2 or greater than 8), it may be difficult to form MgInₓO_{y} films having a large number of inverse spinel structures.

Table 2 below shows the grain sizes of MgInₓO_{y} films before and after heat treatment in Examples 1 to 5. In this regard, the grain sizes are values calculated using the Debye-Scherrer relation based on the measurement results of XRD.

TABLE 2

| | In | Before heat treatment | | After heat treatment | |
|---|---|---|---|---|---|
| | concentration | FWHM | Grain size | FWHM | Grain size |
| | (at. %) | (radian) | (nm) | (radian) | (nm) |
| Example 1 | 43.3 | 0.101 | 1.1 | 0.087 | 1.3 |
| Example 2 | 50.1 | 0.091 | 1.2 | 0.077 | 1.5 |
| Example 3 | 56.5 | 0.075 | 1.5 | 0.063 | 1.8 |
| Example 4 | 65.5 | 0.054 | 2.1 | 0.042 | 2.7 |
| Example 5 | 72.0 | 0.058 | 1.9 | 0.052 | 2.1 |

Referring to Table 2, it was confirmed that the MgInₓO_{y} film of Example 4 has the largest grain size both before and after the heat treatment. Accordingly, when the MgInₓO_{y} film of Example 4 is applied to a device, it is expected that the electrical properties and reliability can be significantly improved by the improved mobility of the device. In addition, if the In concentration is the same, it was confirmed that when the heat treatment is performed, the grains of the MgInₓO_{y} film become larger than when the heat treatment is not performed. Through this, it was confirmed that the grain size can be increased by performing the heat treatment. As a result, it is expected that the electrical properties and reliability can be improved by the improved mobility of the device.

Table 3 below shows the film densities of the MgInₓO_{y} film before and after heat treatment in Examples 1 to 5 obtained through XRR.

TABLE 3

| | |
|---|---|
| In | Film density (g/cm³) |

| | Concentration | Before | After |
|---|---|---|---|
| | (at. %) | heat treatment | heat treatment |
| Example 1 | 43.3 | 6.10 | 5.41 |
| Example 2 | 50.1 | 6.27 | 5.78 |
| Example 3 | 56.5 | 6.54 | 5.93 |
| Example 4 | 65.5 | 6.91 | 6.39 |
| Example 5 | 72.0 | 6.89 | 6.48 |

Referring to Table 3, if the In concentration is the same, it was confirmed that when the heat treatment is performed, the film density of the MgInₓO_{y} film is lower than when the heat treatment is not performed. In addition, it was confirmed that the film density of Example 4 is greater than that of Example 5 before the heat treatment, and that the film density of Example 4 is less than that of Example 5 after the heat treatment. It is expected that the change trend of the film density according to the composition of the MgInₓO_{y} film is related to the crystallinity of the MgInₓO_{y} film. Specifically, as shown in FIGS. 2 and 3, the peak increases as the In composition of the MgInₓO_{y} film increases, which confirms the intensification of crystal growth according to the increase in the In composition. In addition, it is confirmed in Table 3 that as the In composition increases (i.e., as the crystal growth intensifies), the film density of the MgInₓO_{y} film increases.

Table 4 below shows the electrical properties of the MgInₓO_{y} film before and after heat treatment for Example 4.

TABLE 4

| | Carrier | | Hole |
|---|---|---|---|
| | concentration | Resistivity | mobility |
| | (×10¹⁸ cm⁻³) | (×10⁻⁴ ohm*cm) | (cm²/V*s) |
| Before heat treatment | 35.0 ± 8.4 | 133.1 ± 2.6 | 14.2 ± 3.3 |
| After heat treatment | 34.4 ± 1.7 | 95.7 ± 1.4 | 19.1 ± 0.7 |

Referring to Table 4, it was confirmed that the MgInₓO_{y} film that has not been subjected to heat treatment has a carrier concentration and hole mobility similar to those of the MgInₓO_{y} film that has been subjected to a heat treatment. This is in contrast to a MgInₓO_{y} film formed through sputtering, which generally does not have sufficient electrical conductivity and therefore necessarily requires an additional heat treatment process or ion implantation process to improve electrical conductivity. Unlike the sputtering process, a sufficient amount of hydrogen can be introduced into the MgInₓO_{y} film in the ALD process of the first and second processes, and the introduced hydrogen acts as a dopant, thereby improving the electrical conductivity of the MgInₓO_{y} film even without heat treatment. That is, when the MgInₓO_{y} film is formed by a cycle including the first and second processes described above, the MgInₓO_{y} film having sufficient electrical conductivity can be formed even without necessarily performing heat treatment, which makes it possible to reduce the process time and cost.

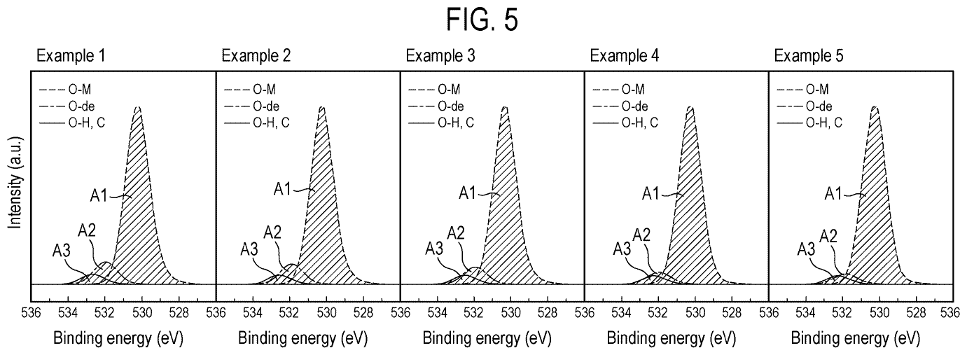

FIG. 5 shows the results of XPS O 1s analysis performed on the MgInₓO_{y} films of Examples 1 to 5 that were not subjected to heat treatment. In FIG. 5, the XPS O1s peaks are separately shown according to the oxygen bonding state. Table 5 below numerically shows the area of O-Metal (A1), the area of O-defect (A2), and the areas of O—H and O—C(A3) in the XPS O1s analysis of FIG. 5.

TABLE 5

| | In | | | | |
|---|---|---|---|---|---|
| | Concentration | Relative area (%) | | | Total area |
| | (at. %) | A1 | A2 | A3 | (%) |
| Example 1 | 43.3 | 85.0 | 10.4 | 4.6 | 100 |
| Example 2 | 50.1 | 86.0 | 9.7 | 4.3 | 100 |
| Example 3 | 56.5 | 87.3 | 8.4 | 4.3 | 100 |
| Example 4 | 65.5 | 89.6 | 6.1 | 4.3 | 100 |
| Example 5 | 72.0 | 90.6 | 5.1 | 4.3 | 100 |

Referring to FIG. 5 and Table 5, it was confirmed that as the In concentration increases in the Examples, the O-defect tends to decrease. It is expected that this result occurs because the Mg-containing precursor, Mg(EtCp)₂, contains a larger amount of impurities such as C and the like than the In-containing precursor, TMI, and the frequency of O exposure to Mg(EtCp)₂ decreases as the In concentration increases. In addition, it appears that the O-defect decreases according to the improvement in crystallinity of the MgInₓO_{y} film due to the increase in In content in the MgInₓO_{y} film. When calculating the atomic percentages of H, C, and N for O—H, O—C and O—N based on the percentage composition of O and the percentages of O—H, O—C and O—N of O 1s, it was confirmed that each of H, C and N is contained at 3 at. % or less.

Hereinafter, the characteristics of a device to which the MgInₓO_{y} film formed through the method according to the present disclosure is applied will be described in detail through Examples.

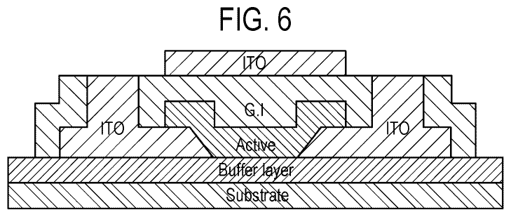

FIG. 6 is a view illustrating a device to which a MgInₓO_{y} film is applied. The device of FIG. 6 is a device having a top gate bottom contact structure. Examples 6 to 10 are related to the same device as that of FIG. 6, and the MgInₓO_{y} films of Examples 1 to 5, which have been subjected to heat treatment, were applied to the active layer in each of the devices of Examples 6 to 10.

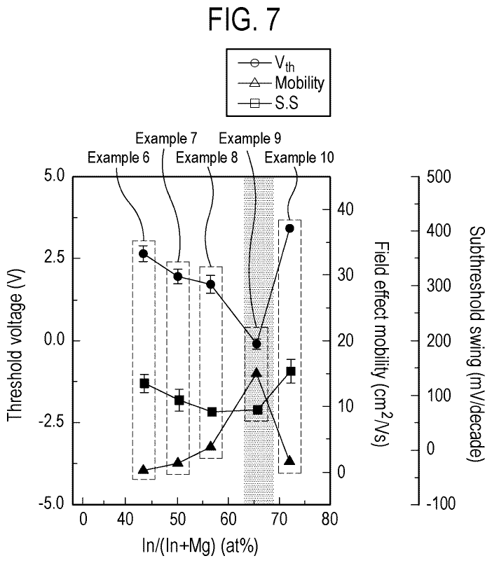

Table 6 below shows the characteristics of the devices depending on the In concentration in Examples 6 to 10 and Comparative Example 4. Specifically, Table 6 below shows the threshold voltage (Vₜₕ), the mobility (μ_{0.1V} and μ_{1.0V}) when V_{DS} is 0.1V and 1V, respectively, subthreshold swing (S.S), and hysteresis according to the rise and fall of the gate voltage between −5V and 5V, which are the electrical characteristics of the devices. In this regard, Comparative Example 4 is a device in which an IGZO (Indium Gallium Zinc Oxide) film is used as an active layer. Other components of the device in Comparative Example 4, except for the active layer, were formed under the same conditions as in Examples 6 to 10. The IGZO film of Comparative Example 4 has an In:Ga:Zn atomic ratio of 4:3:3. FIG. 7 is a graph showing the characteristics of the devices of Examples 6 to 10 described in Table 6.

TABLE 6

| | In | | | | S.S | |
|---|---|---|---|---|---|---|
| | Concentration | Vₜₕ | μ_{0.1V} | μ_{0.1V} | (mV/ | Hysteresis |
| | (at. %) | (V) | (cm²/V*s) | (cm²/V*s) | decade) | (V) |
| Example 6 | 43.3 | 2.7 ± 0.2 | 0.3 ± 0.0 | 0.3 ± 0.1 | 120.7 ± 16.3 | 0.1 ± 0.0 |
| Example 7 | 50.1 | 2.0 ± 0.2 | 1.4 ± 0.2 | 1.4 ± 0.1 | 90.9 ± 20.1 | 0.1 ± 0.0 |
| Example 8 | 56.5 | 1.7 ± 0.3 | 3.9 ± 0.2 | 3.8 ± 0.2 | 69.2 ± 3.7 | 0.1 ± 0.1 |
| Example 9 | 65.5 | −0.1 ± 0.1 | 15.1 ± 0.3 | 15.0 ± 0.3 | 73.1 ± 5.2 | 0.0 ± 0.0 |
| Example 10 | 72.0 | 3.4 ± 0.1 | 1.7 ± 0.3 | 1.6 ± 0.2 | 144.5 ± 21.4 | 0.2 ± 0.0 |
| Comparative | — | 0.7 ± 0.1 | 13.4 ± 0.3 | 11.9 ± 0.3 | 90.1 ± 7.2 | 0.0 ± 0.0 |
| Example 4 | | | | | | |

Referring to FIG. 7 and Table 6, the devices of Examples 6 to 10 to which the MgInₓO_{y} film formed by the method according to the present disclosure is applied have electrical properties similar to those of the device of Comparative Example 4. In particular, the device of Example 9 has a low S.S. value along with high mobility, which confirms that the device can have excellent electrical properties and reliability when the In concentration of the MgInₓO_{y} film, which is the active layer, is similar to 65.5 at. %.

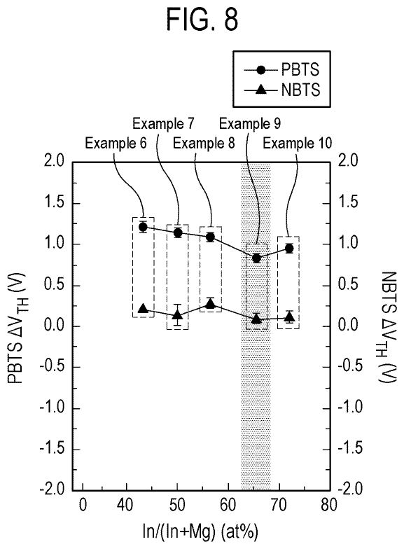

FIG. 8 is a graph showing the results of stress evaluations for the devices of Examples 6 to 10. Specifically, FIG. 8 shows the change in threshold voltage when the devices of Examples 6 to 10 are subjected to a positive bias temperature stress (PBTS) evaluation and a negative bias temperature stress (NBTS) evaluation by inducing an electric field of ±2 MV/cm for 3600 seconds at 95 degrees C. while blocking external light. As a result of the PBTS evaluation and the NBTS evaluation, it was confirmed that the device of Example 9 shows the smallest change in threshold voltage.

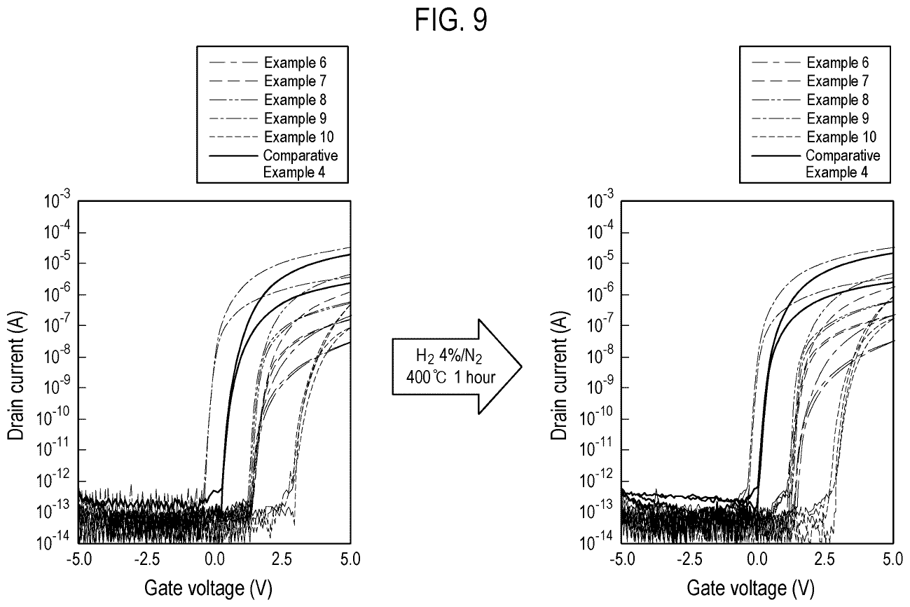

FIG. 9 is a graph showing changes in the characteristics of the devices depending on the hydrogen (H) exposure for Examples 6 to 10 and Comparative Example 4. The left graph of FIG. 9 shows changes in the source-drain current depending on the gate voltage and the source-drain voltage of the devices of Examples 6 to 10 and Comparative Example 4 that were not exposed to H. The right graph shows changes in the source-drain current depending on the gate voltage and the source-drain voltage of the devices of Examples 6 to 10 and Comparative Example 4 after they were exposed to 4% of H₂ and N₂ at 400 degrees C. for 1 hour. Referring to FIG. 9, the devices of Examples 6 to 10 to which the MgInₓO_{y} film is applied did not have a significant difference in the threshold voltage or the source-drain current value from the value before exposure to H, even when they are exposed to H for a long time in a high-temperature environment. This is interpreted as meaning that since the MgInₓO_{y} film applied in Examples 6 to 10 has H resistance, even when the devices are exposed to H, the change in the device characteristics due to hydrogen is minimal. That is, in the case of a device to which the MgInₓO_{y} film is applied, since the H resistance of the MgInₓO_{y} film is high, the deterioration of characteristics (e.g., reduction in electron mobility, etc.) due to H can be minimized. As a result, the electrical properties and reliability of the device can be improved.

Although the technical spirit of the present disclosure has been described by the examples described in some embodiments and illustrated in the accompanying drawings, it should be noted that various substitutions, modifications, and changes can be made without departing from the scope of the present disclosure which can be understood by those skilled in the art to which the present disclosure pertains. In addition, it should be noted that such substitutions, modifications, and changes are intended to fall within the scope of the appended claims.

What is claimed is:

1. A method of manufacturing a MgInₓO_{y} film, wherein x>0 and y>0, the method comprising:
performing one or more cycles of an atomic layer deposition process,
wherein each of the one or more cycles includes performing a first process and a second process,
wherein the first process includes:
supplying a first precursor containing magnesium (Mg) to a substrate; and
supplying a first reactant to the substrate such that the first reactant reacts with the first precursor to form a first intermediate layer on the substrate, and
wherein the second process includes:
supplying a second precursor containing indium (In) to the substrate; and
supplying a second reactant to the substrate such that the second reactant reacts with the second precursor to form a second intermediate layer on the substrate.

2. The method of claim 1, wherein the first process or the second process is performed at a temperature of 100 degrees C. to 400 degrees C.

3. The method of claim 1, wherein each of the one or more cycles includes performing the first process n times (where n is an integer greater than or equal to 1) and the second process m times (where m is an integer greater than or equal to n).

4. The method of claim 3, wherein a ratio m/n has a value in a range of 2 to 8.

5. The method of claim 1, wherein in the MgInₓO_{y} film, a ratio of the number of In atoms to the sum of the number of magnesium (Mg) and indium (In) atoms has a value in a range of 43.3 at. % to 72 at. %.

6. The method of claim 1, further comprising:
performing a heat treatment process on the substrate after performing the one or more cycles,
wherein the heat treatment process is performed at a temperature of 500 degrees C. or lower.

7. The method of claim 1, wherein the MgInₓO_{y} film has a (311) crystal plane.

8. The method of claim 1, wherein the MgInₓO_{y} film has an inverse spinel structure.

9. The method of claim 1, wherein the first precursor includes at least one of Mg(EtCp)₂, Mg(Cp)₂, Mg(thd)₂, or derivatives thereof.

10. The method of claim 1, wherein the second precursor includes at least one of TMI, DADI, DMION, DBADMIn, or derivatives thereof.

11. The method of claim 1, wherein the MgInₓO_{y} film contains impurities.

12. The method of claim 11, wherein the impurities include at least one of carbon, nitrogen, or hydrogen.

13. The method of claim 11, further comprising:
performing a heat treatment process on the substrate after performing the one or more cycles,
wherein the heat treatment process is performed at a temperature of 500 degrees C. or lower.

14. The method of claim 1, wherein in each of the one or more cycles, the first process and the second process are performed sequentially, or the second process and the first process are performed sequentially.

15. A MgInₓO_{y} film containing impurities, wherein x>0 and y>0.

16. The film of claim 15, wherein the impurities include at least one of carbon, nitrogen, or hydrogen.

17. The film of claim 15, wherein in the MgInₓO_{y} film, a ratio of the number of In atoms to the sum of the number of magnesium (Mg) and indium (In) atoms has a value in a range of 43.3 at. % to 72 at. %.

18. The film of claim 15, wherein the film is formed by performing a heat treatment process, and the heat treatment process is performed at a temperature of 500 degrees C. or lower.

19. The film of claim 15, wherein the MgInₓO_{y} film has a (311) crystal plane.

20. The film of claim 15, wherein the MgInₓO_{y} film has an inverse spinel structure.
